(19) United States
(12) Patent Application Publication
(10) Pub. No.: US 2003/0092214 A1
(43) Pub. Date: May 15, 2003

(54) Method and configuration for reducing the electrical contact resistance in organic field-effect transistors by embedding nanoparticles to produce field boosting at the interface between the contact material and the organic semiconductor material

(76) Inventors: Hagen Klauk, Erlangen (DE); Gunter Schmid, Hemhofen (DE)

Correspondence Address: LERNER AND GREENBERG, P.A., Post Office Box 2480, Hollywood, FL, 33022-2480, US

(21) Appl. No.: 10/283,914

(22) Filed: Oct. 30, 2002

(30) Foreign Application Priority Data
Oct. 30, 2001 (DE) 101 53 562.7

(51) Int. Cl. H01L 35/24; H01L 21/00; H01L 51/40; H01L 51/00

(52) U.S. Cl. 438/99; 438/82; 257/40

(57) ABSTRACT

A method for fabricating semiconductor devices based on organic semiconductor materials and in which an electrical contact resistance between a first body and a second body, of which one is composed of an organic semiconductor material and the other is composed of a contact material, is minimized by embedding nanoparticles at a contact area between the two bodies.

### BACKGROUND OF THE INVENTION

### FIELD OF THE INVENTION

The invention relates to a method for fabricating a semiconductor device having at least one contact area between at least one first body, on one hand, and at least one second body, on the other hand, in each case one of the two bodies being composed of an organic semiconductor material and the other body being composed of a contact material. The invention, furthermore, relates to a semiconductor device that is fabricated by the method and in which nanoparticles are embedded at at least one contact area between a contact material and an organic semiconductor material. In the case of the semiconductor device according to the invention, the electrical contact resistance between the two bodies is minimized by field boosting by nanoparticles embedded at the contact area.

Field-effect transistors are used as switches in electronic circuits. A semiconductor disposed between a source electrode and a drain electrode constructed from electrically conductive material in each case acts as an insulator in the switched-off state of the transistor, while a charge carrier channel forms under the influence of the field of a gate electrode in the switched-on state of the transistor. In such a case, electrical charge carriers are injected into the semiconductor layer at the source contact and extracted from the semiconductor layer at the drain contact so that an electric current flows from source to drain through the semiconductor layer or through the charge channel produced in the semiconductor layer.

Due to the different Fermi levels of semiconductor material and contact material, an asymmetrical diffusion process occurs at the contact area of the two materials. The different energy of the Fermi levels of the two materials gives rise to an energy difference, which is compensated for by the crossing of charge carriers. As a consequence, an interface potential builds up that, when an external potential difference is applied, counteracts crossing of the charge carriers between the two layers. A potential barrier is, thus, produced, which has to be surmounted by the charge carriers when entering into the semiconductor material from the electrically conductive contact or when emerging from the semiconductor material into the electrically conductive contact. In such a case, the tunneling current produced as a result of the charge carriers tunneling through the potential barrier is smaller, the higher or wider the potential barrier. A low tunneling current corresponds to a high contact resistance.

In semiconductor components based on inorganic semiconductors, an increase in the contact resistance is combated by doping the inorganic semiconductor in a boundary layer oriented toward the contact area. The doping alters the energy of the Fermi level in the inorganic semiconductor, i.e., the difference between the Fermi levels of contact material and semiconductor material decreases. As a consequence, either the potential barrier is reduced, as a result of which a significantly larger number of charge carriers pass over the potential barrier into the material opposite, or the potential barrier is narrowed, as a result of which the probability of charge carriers tunneling through the potential barrier increases. In both cases, the contact resistance is reduced on account of the doping.

In the fabrication of field-effect transistors based on amorphous or polycrystalline silicon layers, the contact regions are doped by the introduction of phosphorus or boron to the silicon layer near the source and drain contacts. The phosphorus or boron atoms are incorporated into the silicon network and act as charge donors or charge acceptors, thereby increasing the density of the free charge carriers and, thus, the electrical conductivity of the silicon in the doped region. This reduces the difference between the Fermi levels of contact material and doped semiconductor material. In such a case, the doping substance is introduced into the silicon only in the region of the source and drain contacts, but not in the channel region in which a charge carrier channel forms under the influence of the field of the gate electrode. Because phosphorus and boron form covalent bonds with the silicon, there is no risk of these atoms diffusing into the channel region so that a low electrical conductivity in the channel region is, furthermore, guaranteed.

If the doping of the contact regions is high enough, the tunneling probability is already so high in the quiescent state that the junction between the contact material and the inorganic semiconductor material loses its blocking capability and becomes readily conductive in both directions.

As an alternative to a doping of the inorganic semiconductor material, Narayanan et al., “Reduction of Metal-Semiconductor Contact Resistance by Embedded Nanocrystals”, 2000 International Electron Device Meeting Technical Digest, propose reducing the contact resistance between an inorganic semiconductor material and a contact material by embedding nanoparticles.

To that end, a thin gold layer is vapor-deposited onto a silicon wafer and is converted subsequently into a layer of isolated gold nanoparticles by heating. In such a case, for the material combination silicon/gold, the crystallization of the gold layer in the form of nanoparticles is promoted and controlled by reducing the surface energy on the silicon surface. After the formation of the nanoparticles, a layer of tungsten is deposited as contact material. For the contact resistance measured between the silicon wafer and the tungsten layer, a reduction by the factor 100 results from embedding the gold nanoparticles.

Field-effect transistors based on organic semiconductor materials are of interest for a multiplicity of electronic applications that require extremely low manufacturing costs, flexible or unbreakable substrates, or the fabrication of transistors and integrated circuits over large active areas. By way of example, organic field-effect transistors are suitable as pixel control elements in active matrix screens. Such screens are usually fabricated with field-effect transistors based on amorphous or polycrystalline silicon layers. The temperatures of usually more than 250° C. that are necessary for fabricating high-quality transistors based on amorphous or polycrystalline silicon layers require the use of rigid and fragile glass or quartz substrates. By virtue of the relatively low temperatures at which transistors based on organic semiconductors are fabricated, usually of less than 100° C., organic transistors allow the fabrication of active matrix screens using inexpensive, flexible, transparent, unbreakable polymer films, with considerable advantages over glass or quartz substrates.

A further area of application for organic field-effect transistors is the fabrication of highly cost-effective integrated circuits, as are used, for example, for the active marking and identification of merchandise and goods. These so-called transponders are usually fabricated using integrated circuits based on monocrystalline silicon, which leads to considerable costs in the construction and connection technology. The fabrication of transponders based upon organic transistors would lead to huge cost reductions and could help the transponder technology to achieve worldwide success.

One of the main problems in the application of organic field-effect transistors is the relatively poor electrical properties of the source and drain contacts, i.e., the high contact resistances thereof. The source and drain contacts of organic transistors are usually produced using inorganic metals or with the aid of conductive polymers, in order, thus, to ensure the highest possible electrical conductivity of the contacts. Most organic semiconductor materials that are appropriate for use in organic field-effect transistors have very low electrical conductivities. By way of example, pentazene, which is often used for fabricating organic field-effect transistors, has a very low electrical conductivity of 10⁻¹⁴ Ω⁻¹ cm⁻¹. If the organic semiconductor has a low electrical conductivity, a large difference between the Fermi levels of electrically conductive contact material and organic semiconductor material, therefore, exists at the contact area. Such a condition leads to the formation of a high potential barrier with a low tunneling probability for the passage of electrons. Therefore, source and drain contacts often have very high contact resistances, which has the effect that high electrical field strengths are necessary at the contacts to inject and extract charge carriers. A restrictive effect is, thus, brought about not by the conductivity of the contacts themselves, but by the conductivity of the semiconductor regions that adjoin the contacts and into or from which the charge carriers are injected or extracted.

To improve the electrical properties of the source and drain contacts, therefore, a high electrical conductivity of the organic semiconductor material in the regions adjoining the contacts is desirable to reduce the difference in the Fermi levels between organic semiconductor material and contact material and, thus, to lower the contact resistances. On the other hand, a high electrical conductivity of the organic semiconductor material in the channel region adversely influences the properties of the transistor. An appreciable electrical conductivity in the channel region inevitably leads to high leakage currents, that is to say, to relatively high electric current intensities in the switched-off state of the field-effect transistor. For many applications, however, low leakage currents in the region of 10⁻¹² A or less are indispensable. Moreover, a high electrical conductivity has the effect that the ratio between maximum switch-on current and minimum switch-off current turns out to be too small. Many applications require the largest possible ratio between switch-on current and switch-off current in the region of 10⁷ or greater because such a ratio reflects the modulation behavior and the gain of the transistor. Therefore, a low electrical conductivity of the organic semiconductor material is necessary in the channel region, while a high electrical conductivity is necessary in the region of the source and drain contacts, in order to improve the contact properties between organic semiconductor material and the material of the contacts.

As in the case of inorganic semiconductors, the electrical conductivity of many organic semiconductor materials can be increased by the introduction of suitable doping substances.

Obtaining positional selectivity in the course of doping is problematic, however. The doping substances are not bound to a specific position in the organic semiconductors and can move freely within the material. Even if the doping process can originally be restricted to a specific region, for example, the regions around the source and drain contacts, the doping substances later migrate through the entire organic semiconductor layer, in particular, under the influence of the electric field applied between the source and drain contacts in order to operate the transistor. The electrical conductivity in the channel region is inevitably increased by the diffusion of the doping substances within the organic semiconductor layer.

### SUMMARY OF THE INVENTION

It is accordingly an object of the invention to provide a method for fabricating semiconductor devices, based on organic semiconductor materials, and for reducing the electrical contact resistance in organic field-effect transistors by embedding nanoparticles in order to produce field boosting at the interface between the contact material and the organic semiconductor material that overcomes the hereinafore-mentioned disadvantages of the heretofore-known devices and methods of this general type and that can minimize the electrical contact resistance at the contact area between a body made of a contact material and a body made of an organic semiconductor material.

With the foregoing and other objects in view, there is provided, in accordance with the invention, a method for fabricating a semiconductor device having at least one first body and at least one second body, including the steps of providing one of the first and second bodies from an organic semiconductor material and providing another one of the first and second bodies from a contact material, the first and second bodies together forming a common contact area therebetween, providing the first body with a surface, applying isolated nanoparticles of a particle material on at least sections of the surface of the first body, the contact material and the particle material having different work functions, and applying the second body at least on sections of the surface of the first body covered by the nanoparticles, the sections of the surface covered by the second body fashioning contact areas.

Thus, in the case of the method according to the invention, isolated nanoparticles made of a particle material are applied on the entire surface or selectively in sections of the surface of a first body. In such a connection, isolated means that the nanoparticles do not form a continuous area, but, rather, are disposed spaced apart from one another on the surface of the first body. Thus, the surfaces of the nanoparticles do not touch one another. Afterward, a second body is applied at least in the sections of the surface of the first body that are covered by the nanoparticles, a contact area being fashioned between the two bodies. In such a case, one of the two bodies is composed of an organic semiconductor material and the second body is composed of a contact material. The contact material and the particle material have different work functions.

The contact material may be an electrically conductive metal, for instance, gold, titanium, or palladium, or an electrically conductive polymer, such as, for example, polyaniline doped with camphor sulfonic acid or poly(dioxyethylene) thiophene doped with polystyrenesulfonic acid. The contact material should have the highest possible electrical conductivity.

The nanoparticles are composed of a particle material that has a different work function than the contact material.

Nanoparticles in the sense of the invention are understood to be particles having a size of 0.1 nm to 5000 nm. The particles may have a spherical shape, that is to say, have the extents specified above in all three spatial directions. However, it is also possible to use two- or one-dimensional nanoparticles, which, then, have the form of disks or rods or tubes. The nanoparticles, then, have the dimensions specified above in one or two spatial directions, while the particles may also have a larger extent, for example, through to a plurality of micrometers, in the remaining dimensions.

Both organic and inorganic substances are suitable as particle material. Thus, for instance, polyaniline in its form doped with camphor sulfonic acid, for instance, is always present as a suspension with varying particle size. A further example of an organic particle material is 3,4-polyethylenedioxythiophene that has been doped with polystyrenesulfonic acid. Graphite or fullerene clusters are also suitable.

Elementary or binary semiconductors, for instance, silicon, silicon carbide, gallium arsenide, and indium phosphide, are further suitable as particle material.

A metal or a metal compound is, preferably, chosen as particle material. In particular, metal oxides, metal chalkogenides, and metal hydroxides are suitable as metal compound.

The size of the nanoparticles results, for instance, in the course of the formation of nanoparticles from a colloidal precursor in a dispersion. In the dispersion, the coagulation of the particles is limited by the surface charges that form on the surfaces of the nanoparticles. An equilibrium state is established between forces conducive and obstructive to the coagulation at a specific particle size.

The distance between the nanoparticles disposed in isolated fashion on the surface determines the extent of an average field boosting at the interface between organic semiconductor material and contact material. The distance between the nanoparticles disposed in the sections of the surface of the first body is on average about 0.1 nm to 5000 nm.

The tunneling probability for the crossing of charge carriers between a contact material and an organic semiconductor material over a contact area can be increased by embedding nanoparticles at the contact area between the contact material and the organic semiconductor material. If the particle material and the contact material have different work functions for the charge carriers, then there arise asymmetrical diffusion processes of charge carriers at the contact area between the nanoparticles, on one hand, and the layer formed from the contact material, on the other hand. The resulting interface potential between the nanoparticles and the contact material is compensated for on account of the high electrical conductivities in the two materials to very short distances, a few tenths of nanometers. This leads to high electric field strengths between the nanoparticles and the contact material of the order of magnitude of about 10⁷ to 5×10⁷ V/cm.

Such an electric field is superposed on the field that builds up at the junctions between semiconductor and contact material. The increased electric field strength leads to a narrower potential barrier at the contact area and, thus, to an increase in the tunneling probability and a tunneling current between the semiconductor and the contact material. The increased tunneling current reduces the contact resistance. The increase in the field strength at the contact area is all the more pronounced, the larger the difference between the work function of the-particle material and the work function of the contact material.

Semiconductor devices based on organic semiconductor materials are usually embodied in a layer technology. Preferably, therefore, the first body is applied as a first layer on a substrate. Afterward, the nanoparticles are applied on at least sections of that surface of the first layer that is opposite to the substrate and the second body is applied as a second layer at least on the sections that are covered by nanoparticles and correspond to the later contact areas. Depending on the method implementation and construction of the configuration containing the semiconductor device, the entire surface of the first layer can be covered with nanoparticles, in which case only sections of the surface covered with nanoparticles also form the contact areas, or it is also possible to cover only the sections of the surface with nanoparticles that later also form the contact areas.

In structures as are used in organic field-effect transistors, the first layer, which, here, forms the first body, is composed, for example, of the organic semiconductor material, and two electrodes, the source electrode and the drain electrode, are disposed as respective second bodies on that surface of the first layer that is opposite to the substrate. In such a structure, only sections of that surface of the first body or of the first layer that is opposite to the substrate are contact areas. Accordingly, the nanoparticles are, preferably, applied only in the sections of the surface of the first body that correspond to the contact areas. Thus, the nanoparticles have to be applied section by section in such a case. However, it is also possible to apply nanoparticles on the entire surface of the first body or at the very least in regions larger than those that later correspond to the contact areas, and later to form contact areas only in sections of the regions covered with nanoparticles.

The nanoparticles can be applied section by section, for example, with the aid of a mask, a stencil, or a printer.

For such section-by-section application of the nanoparticles that surface of the first body that is opposite to the substrate can also be modified such that the sections in which the nanoparticles are intended to be bound to the surface differ in their chemical or physical properties from the sections that are intended to remain free of nanoparticles. If the nanoparticles are, then, applied nonspecifically to the surface, e.g., by the latter being wetted with a solution or a suspension of the nanoparticles, the nanoparticles are bound on the sections of the later contact areas, while they are not bound in the other sections of the surface and can be removed in a rinsing step with a suitable rinsing medium so that these sections remain free of nanoparticles. Section-by-section application of the nanoparticles to the previously modified sections can also be effected by one of the abovementioned methods for section-by-section application of the nanoparticles, that is to say, for example, with the aid of a mask, a stencil, or a printer.

Generally, all mechanisms by which nanoparticles can be fixed on a surface can also be utilized for section-by-section deposition of the nanoparticles. An overview of methods by which surfaces of nanoparticles can be modified such that they adhere well on the working area formed by the contact material or by the organic semiconductor material is given in J. Schmitt et al., “Metal Nanoparticle/Polymer Superlattice Films: Fabrication and Control of Layer Structure” Advanced Materials 9, 1997, page 61.

The surface of the first body can be modified section by section, for example, by ligands being applied in the sections that later form the contact areas, the ligands being at least bifunctional. The ligands, then, bind to the surface of the first body with one of the functional groups, while the other functional group can act as coordination site for the fixing of the nanoparticles.

For section-by-section modification of the surface of the first body, it is possible, for example, to utilize the fact that nanoparticles usually have a surface charge. Such a surface charge is possessed by, for example, nanoparticles that originate from a colloidal solution. Such a surface charge arises, for example, through inherent dissociation or through preferred adsorption of an ion species from the solution. By way of example, colloidal metals adsorb hydroxide ions from the water and are, thereby, charged negatively. Because nanoparticles (or their colloidal precursor) of one type are charged in each case with a surface charge of identical polarity, the surface charge counteracts further coagulation of the particles and stabilizes them.

For section-by-section application of the nanoparticles, the surface of the first body is, then, functionalized section-by-section with ionic groups. Finally, the nanoparticles are applied over the whole area or in sections on the modified surface. Under the control of electrostatic forces or neutralization of their surface charge, the nanoparticles are, then, preferably deposited on the modified sections of the surface.

Because the nanoparticles are repelled from one another on account of their surface charge of identical polarity, the nanoparticles are deposited in isolated fashion in the modified sections of the working area, i.e., the surfaces of the nanoparticles do not touch one another.

Examples of nanoparticles that form charges at their surfaces are metals, such as, for example, purple of Cassius, copper, silver, palladium, or platinum. Also suitable are metallically conductive or semiconducting metal oxides, such as RuO₂, TiO₂, SnO₂, In₂O₃, SnO₂:In[ITO], and metallically conductive or semiconducting metal chalkogenides, such as CdSe, ZnSe, PbS. In such a case, nanoparticles made of metal hydroxides or metal oxide sols usually form positive surface charges, while nanoparticles made of metals and metal chalkogenides usually have negative surface charges.

Details on properties and syntheses of nanoparticles can be found, for example, in A. F. Hollemann, E. Wiberg, N. Wiberg, Lehrbuch der anorganischen Chemie [Textbook of inorganic chemistry], Walter de Gruyter Verlag, Berlin, 1985, page 767, or else in J. H. Fendler, Nanoparticles and Nanostructure Films—Preparation, Characterization and Applications, Wiley-VCH, 1998.

A surface charge can be produced in sections of the surface of the first body, e.g., by virtue of the fact that ionic groups are anchored on the surface. This can be achieved, for example, with bifunctional ligands, one of the functional groups, for example, a thiol group, coordinating to the surface of the first body, while the other of the functional groups is a positively or negatively charged group that is available for the coordination to nanoparticles.

However, the binding of the nanoparticles can also be effected such that the nanoparticles that are held in the colloidal state by their surface charge are discharged by a group that can dissociate away a positive or negative ion. Examples of such groups are acidic or basic groups that can release a proton or, by taking up a proton, can produce, e.g., hydroxide ions. If the nanoparticles pass into the immediate vicinity of these groups, the ion that can be split off neutralizes the charge present on the surface of the nanoparticles, as a result of which the nanoparticles coagulate selectively in the functionalized sections and are deposited there.

Substances with which a surface charge or ionically dissociatable groups can be selectively applied on sections of the working area are, for example, ω-sulfonic acid octadecanethiol, which can produce a positive surface charge, or splits off protons, and ω-aminooctadecanethiol, which can produce a negative surface charge, or produces, e.g., hydroxide ions by taking up protons. The mechanism according to which the nanoparticles are deposited on the functionalized sections depends, for example, on the pH of the colloidal solution and on the acid constant of the group.

A further possibility for binding nanoparticles by electrostatic interactions at the sections of the surface of the first body lies in functionalizing the surface of the nanoparticles and the sections of the surface of the first body such that both surfaces react with one another with salt formation and the nanoparticles are bound to the surface by an ionic bond. In such an embodiment of the invention, the surface of the nanoparticles and the sections of the surface of the first body are occupied by ligands that bear terminal groups and form an acid-base pair. In this case, the surface of the nanoparticles bears one partner of the acid-base pair and the surface of the first body-bears the other partner. By way of example, the surface of the nanoparticles can be functionalized with amino groups and the surface of the first body can be functionalized with sulfonic acid groups. The nanoparticles are, then, bound to the surface of the first body with formation of an ammonium sulfonate.

The nanoparticles can also be fixed on the sections of the surface of the first body by the formation of a covalent bond. To that end, the nanoparticles and the sections of the surface of the first body are modified such that both areas bear terminal groups that can react with one another to form a covalent bond. To that end, it is possible to use ligands that bear ethinyl groups, for example, as terminal group. If these terminal groups react to form a butadiene system, the nanoparticles are fixed on the surface of the first body by covalent bonding. If one of the areas has hydroxyl groups, it is possible to achieve a covalent bond with a silane to form a siloxane.

In accordance with another mode of the invention, the nanoparticles are bonded by a coordinative bond. To that end, the sections of the surface of the first body or of the nanoparticles are functionalized with ligands that can form a coordinative bond with the particle material or with the material of the first body. To that end, it is possible, by way of example, either to choose a metal or a metal compound as particle material and to functionalize the sections of the surface of the first body with thiols, or, alternatively, a metal or a metal compound is chosen as material of the first body and the surface of the nanoparticles is functionalized with thiols. Thiols bond coordinatively to metal surfaces, which results in fixing of the nanoparticles.

The nanoparticles can be applied on the surface of the first body by various methods. By way of example, firstly a thin layer of a metal, e.g., gold, can be vapor-deposited and the layer can, then, be converted thermally into nanoparticles.

In a particularly preferred manner, however, the nanoparticles are applied in solution or in suspension. The method, thus, largely obviates thermal stressing of the first body or of the already fabricated parts of the semiconductor configuration because it is only necessary to evaporate the solvent. The solvent is chosen such that previously produced structures of the semiconductor configuration are not destroyed and the solvent can easily be removed by evaporation.

Overall, a method in which the nanoparticles are applied in a solution or suspension makes modest requirements of the material of the first body.

When the nanoparticles are applied in solution, the nanoparticles can be produced in solution, for example, firstly from a soluble precursor of the particle material. The solution or the suspension can, then, be applied directly to the surface of the first body and the solvent can, then, be driven out. Preferably, however, the nanoparticles are firstly isolated, e.g., by centrifuging the suspension, in order to be suspended anew after further cleaning in a, possibly different, solvent and applied to the surface of the first body.

The solution can be applied, e.g., by spin-on, printing, pouring, or spraying. A further possibility is to dip the first body into the solution or suspension of the nanoparticles.

Preferably, the nanoparticles are produced from a colloidal precursor and coagulated in solution.

In accordance with a further mode of the invention, the nanoparticles are applied as a colloidal precursor to the surface of the first body and coagulated on the surface of the first body to form nanoparticles.

Equally, it is possible to apply a chemical precursor of the particle material to the surface of the first body, which is converted into the particle material after application, the nanoparticles being produced. An example of a chemical precursor is an oxidized or reduced form of the particle material, from which the nanoparticles are, then, produced by reduction or oxidation.

The method according to the invention is suitable, in particular, for reducing the contact resistance at the drain or source electrode of organic field-effect transistors.

In accordance with an added feature of the invention, gold is chosen as particle material and the solution containing the gold particles is applied to the working area by a printer. An inkjet printer is suitable, for example.

The method according to the invention is used to produce semiconductor devices based on organic semiconductor materials in the case of which an electrical contact resistance between a body made of an organic semiconductor material and a body made of a contact material is minimized. Injection or extraction of charge carriers into or from the organic semiconductor material, then, requires a lower control voltage between the two bodies.

Therefore, the invention also relates to a configuration in a semiconductor device with incorporated nanoparticles at a contact area between a body made of an organic semiconductor material and a body made of a contact material.

With the objects of the invention in view, there is also provided a method for fabricating a field-effect transistor having at least one first body and at least one second body, including the steps of providing one of the first and second bodies from an organic semiconductor material and providing another one of the first and second bodies from a contact material, the first and second bodies together forming a common contact area therebetween, providing the first body with a surface, applying isolated nanoparticles of a particle material on at least sections of the surface of the first body, the contact material and the particle material having different work functions, applying the second body at least on sections of the surface of the first body covered by the nanoparticles, the sections of the surface covered by the second body fashioning contact areas, forming the field-effect transistor with a source electrode, a drain electrode, and a path made of a semiconductor material disposed between the source electrode and the drain electrode with the first and second bodies, and locating the contact areas respectively between the drain and source electrodes and the organic semiconductor material.

With the objects of the invention in view, there is also provided a semiconductor device configuration, including at least one first body, at least one second body, one of the first and second bodies being composed of an organic semiconductor material and another of the first and second bodies being composed of a conductive contact material, at least one contact area disposed between the at least one first body and the at least one second body, and nanoparticles incorporated at the contact area, the nanoparticles of a particle material having a different work function than the contact material.

Because electronic components based on organic semiconductors are predominantly fabricated in a layer technology, the first body is, preferably, disposed at least in sections as a first layer on a substrate and the second body is disposed at least in sections as a second layer on a surface of the first layer that is opposite to the substrate. In such a case, the substrate may be a substrate, a further layer made of a contact material or an organic semiconductor material or dielectric.

During the fabrication process for the semiconductor device, after the application of the nanoparticles and before the application of the second body, the nanoparticles are, preferably, fixed chemically or physically on the surface of the first body. Therefore, the configuration according to the invention, preferably, has, at least between the surface of the nanoparticles and the surface of the first body, a thin, monomolecular or multimolecular auxiliary layer that fixes the nanoparticles on the surface of the first body by an ionic, covalent or coordinative bond. The layer is, preferably, formed from at least bifunctional ligands having a functional group that binds to the surface of the first body and a functional group that binds to the surface of the nanoparticles.

The degree of improvement in the contact resistance depends on the difference between the work functions of the particle material and of the contact material and, to a certain extent, also on the distance between the nanoparticles. The work functions of the particle material and of the contact material, preferably, differ from one another by at least 0.3 eV.

Other features that are considered as characteristic for the invention are set forth in the appended claims.

Although the invention is illustrated and described herein as embodied in a method for reducing the electrical contact resistance in organic field-effect transistors by embedding nanoparticles in order to produce field boosting at the interface between the contact material and the organic semiconductor material, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a fragmentary, simplified, cross-sectional view through a detail of a configuration according to the invention;

FIG. 2 is a fragmentary, simplified, cross-sectional view through an organic field-effect transistor embodiment of the configuration according to the invention;

FIG. 3A is a fragmentary, simplified, cross-sectional view through an alternative embodiment of the organic field-effect transistor structure according to the invention;

FIG. 3B is a fragmentary, simplified, cross-sectional view through an alternative embodiment of the organic field-effect transistor structure according to the invention;

FIGS. 3C and 3D are fragmentary, simplified, cross-sectional views through alternative embodiments of the organic field-effect transistor structure according to the invention, in which the nanoparticles have been provided on the contacts during the fabrication of the transistor;

FIG. 3E is a fragmentary, simplified, cross-sectional view through an alternative embodiment of the organic field-effect transistor structure according to the invention, in which source, drain and gate electrodes are disposed in one plane; and

FIG. 4 is a fragmentary, simplified, cross-sectional view of a mechanism for selective deposition or fixing of nanoparticles on a functionalized surface according to the invention.

### DESCRIPTION OF THE PREFERRED EMBODIMENTS

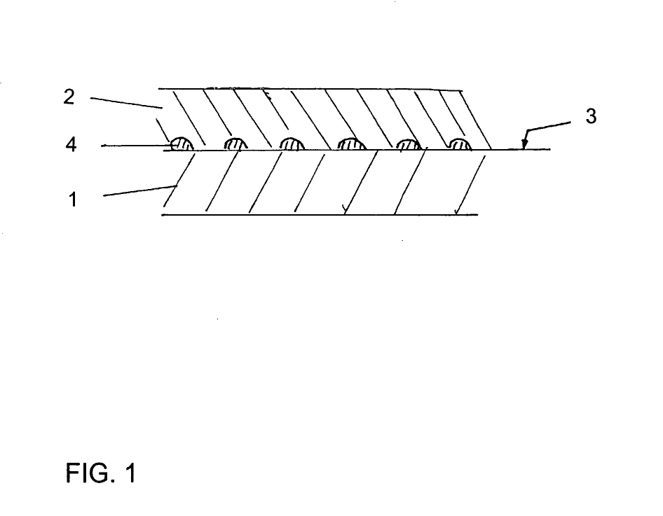

Referring now to the figures of the drawings in detail and first, particularly to FIG. 1 thereof, there is shown a diagrammatic cross-section through a first body 1, a second body 2, and a surface that is fashioned as contact area 3 in the region between first body 1 and second body 2. Isolated, separate nanoparticles 4 are disposed on the contact area 3. The nanoparticles 4 have a mean diameter and a mean distance from adjacent nanoparticles 4. The second body 2 is disposed such that it covers a section of the surface that is covered by the nanoparticles 4 and forms the contact area 3. In each case one of the two bodies 1, 2 is composed of a contact material, and the other body is composed of an organic semiconductor material. The nanoparticles 4 are composed of a particle material that has a different work function of the electrons than the contact material.

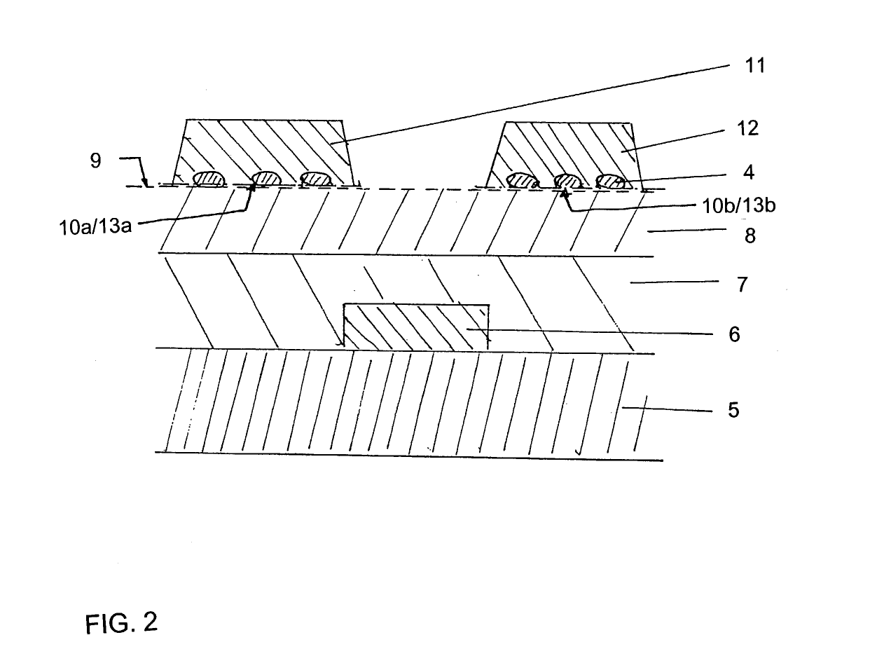

FIG. 2 shows a section through an organic field-effect transistor that illustrates a typical configuration according to the invention. Disposed on a substrate 5 is a gate electrode 6, which is isolated from a first layer 8, fashioned as organic semiconductor layer, by a dielectric 7. The first layer 8 represents the first body here in the sense of the invention. The surface 9 of the first layer 8, which surface is opposite to the dielectric 7, forms sections 10a, 10b on the surface 9 of the first layer 8. Disposed on these sections 10a, 10b are source and drain electrodes 11, 12 as second bodies in the sense of the invention. Source and drain electrodes 11, 12 are composed of a contact material. The sections 10a, 10b of the surface 9 between the first layer 8 made of the organic semiconductor material and the source and drain electrodes 11, 12 made of the contact material form contact areas 13a, 13b. Separate nanoparticles 4 are embedded at the contact areas 13a, 13b. The particle material and the contact material have different work functions.

If the particle material has a higher work function than the contact material, then electrons can cross more easily from the contact material into the particle material than vice-versa. An asymmetrical diffusion process takes place, on account of which an interface potential builds up between nanoparticles, on one hand, and the contact material, on the other hand. The same applies to the interface between the organic semiconductor material and the contact material. The two fields are superposed. Field boosting occurs. The width of a potential barrier between the organic semiconductor material and the contact material decreases. As a result, the probability of electrons tunneling through the potential barrier rises. The electrical conductivity of the contact area is increased.

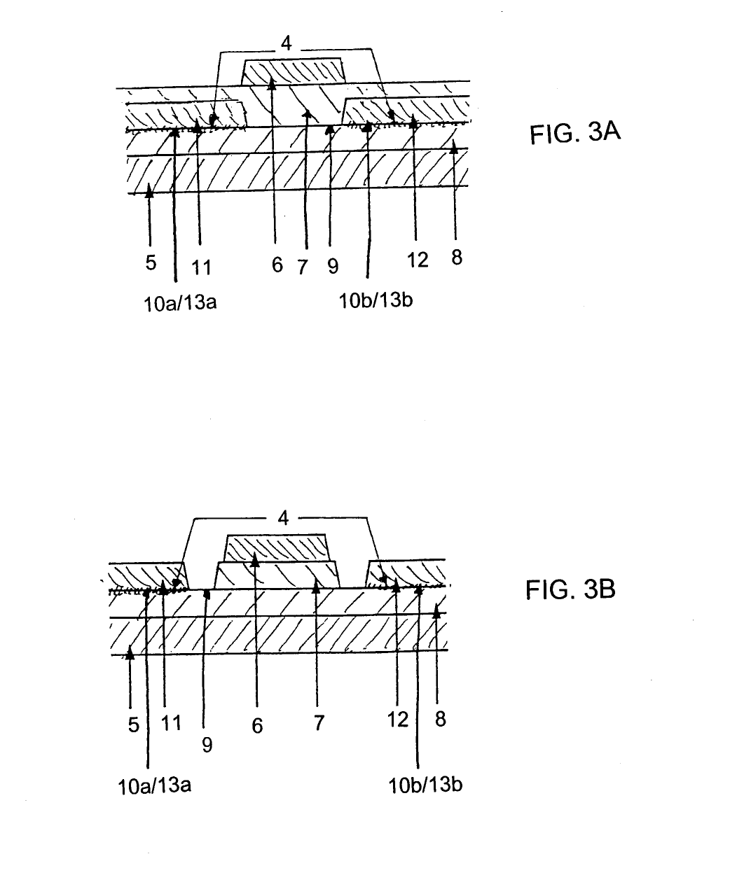

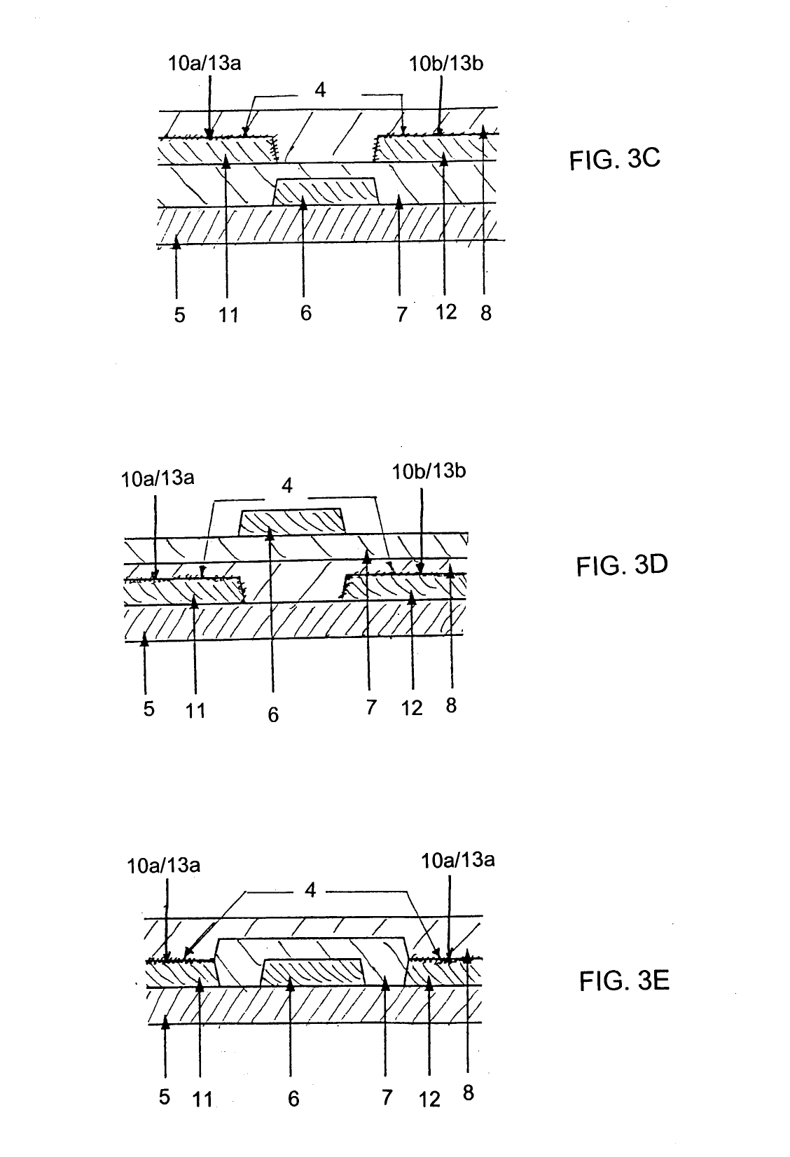

FIG. 3 shows cross-sections through further embodiments of field-effect transistors that can be fabricated by the method according to the invention and include the semiconductor configurations according to the invention. In the case of the configurations illustrated in FIGS. 3A and 3B, the nanoparticles were deposited on sections of the area of the organic semiconductor layer during the fabrication of the field-effect transistor, while the nanoparticles were deposited on the contacts in the case of the configurations shown in FIGS. 3C, 3D, and 3E.

In the case of the configuration shown in FIG. 3A, first, a layer 8 made of an organic semiconductor material was deposited on the substrate 5. On the layer 8, nanoparticles 4 are disposed in sections 10a, 10b of the area 9 of the organic semiconductor layer 8 that form the contact areas 13a, 13b. The source electrode 11 and the drain electrode 12 are disposed as contacts on the sections 10a, 10b. A gate dielectric 7 for insulation is applied on the source electrode 11, the drain electrode 12, and the uncovered area of the layer 8 made of organic semiconductor material, a gate electrode 6 being disposed, in turn, on the gate dielectric 7.

A modification of the field-effect transistor illustrated in FIG. 3A is shown in FIG. 3B. A layer 8 made of organic semiconductor material is disposed on the substrate 5. Nanoparticles 4 are disposed on the sections 10a, 10b of the area 9 of the layer 8 made of organic semiconductor material. The source electrode 11 and the drain electrode 12 are disposed as contacts on the sections 10a, 10b. In the region of the channel region, a gate dielectric 7 is applied to the layer 8 made of organic semiconductor material, by which the gate electrode 6 is insulated.

In the field-effect transistors illustrated in FIGS. 3C and 3D, the nanoparticles have been provided on the contacts during the fabrication of the transistor.

In FIG. 3C, a gate electrode 6 insulated by a gate dielectric 7 is disposed on a substrate 5. Disposed on the gate dielectric 7 are source electrode 11 and drain electrode 12 as contacts that form respective contact areas 13a, 13b to the layer 8 made of organic semiconductor material that is disposed on the source electrode 11 and the drain electrode 12. Nanoparticles 4 are disposed at the contact area 13a, 13b.

A configuration of a field-effect transistor in which the source electrode 11 and the drain electrode 12 are applied directly on the substrate 7 is shown in FIG. 3D. Nanoparticles 4 are, again, disposed on the sections 10a, 10b of the source electrode 11 and of the drain electrode 12, respectively, which form the contact areas 13a, 13b. The region of the layer 8 made of organic semiconductor material that is disposed between source electrode 11 and drain electrode 12 and that includes the channel region is free of nanoparticles. A gate dielectric 7 is, again, disposed on the layer 8 made of organic semiconductor material, and the gate electrode 6 is disposed on the gate dielectric 7.

A further configuration, in which source electrode 11, drain electrode 12, and gate electrode 6 are disposed in one plane, is illustrated in FIG. 3E. Such a thin-film transistor requires only three steps for the deposition of the individual layers and was proposed, generally, by H. Klauk, D. J. Gundlach, M. Bonse, C. -C. Kuo and T. N. Jackson, Appl. Phys. Lett. 76, 2000, 1692-1694. Firstly, a source electrode 11, a drain electrode 12, and a gate electrode 6 made of an electrically conductive material, in particular, a metal, for example, aluminum, are defined on a substrate 5 in a common work step. Afterward, the gate electrode 6 is insulated with a gate dielectric 7. Nanoparticles 4 are provided on the uncovered sections 10a, 10b of the source electrode 11 and the drain electrode 12 that later form the contact areas 13a, 13b. The layer 8 of the organic semiconductor material is deposited subsequently onto the nanoparticles 4 and also onto the uncovered areas of the gate dielectric 7.

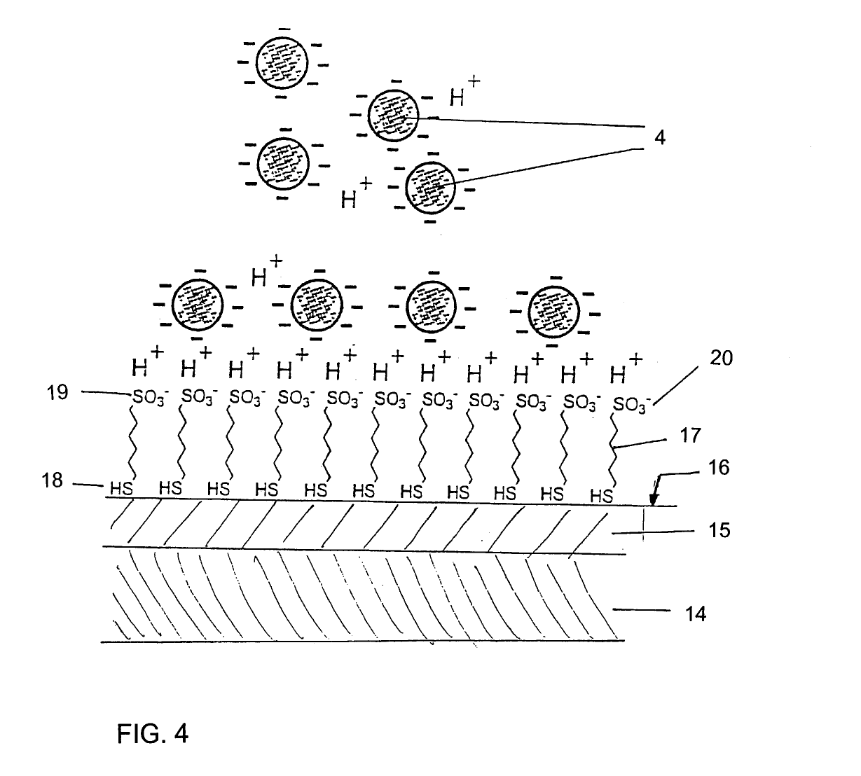

FIG. 4 diagrammatically illustrates a mechanism that enables nanoparticles to be fixed section-by-section. A layer 15 made of a contact material is disposed on a substrate 14. A surface of the layer 15 that is opposite to a substrate 14 forms a section 16 on the surface. The section 16 is functionalized with a bifunctional ligand 17 having a thiol group 18. The thiol group 18 of the ligand 17 is attached to the surface of the contact material in the section or working area 16. The sulfonic acid groups 19 opposite the thiol groups 18 can dissociate and, in the process, release positively charged protons. A solution with nanoparticles 4 is applied on a surface that has been functionalized to such an extent in the sections 16. The nanoparticles 4 have a negatively charged surface charge through dissociation. If nanoparticles pass into the vicinity of the layer 20 formed by the sulfonic acid groups, protons (H⁺) dissociate away from the sulfonic acid groups and neutralize the negative surface charge of the nanoparticles 4, which, thereupon, coagulate and are deposited along the layer 20 of the sulfonic acid groups. Overall, a layer made of nanoparticles 4, thus, forms over the functionalized sections of the working area 16, while no discharge of the nanoparticles, and, thus, no deposition, takes place at non-functionalized sections of the working area 16.

### EXAMPLE

After a cleaning process, a layer made of aluminum is applied on a carrier (e.g., a glass or a polyester film) as substrate, by thermal vaporization, cathode ray sputtering, or printing. Gate electrodes are defined from the layer by photolithography, chemical etching, lift-off, or printing.

Afterward, a layer made of a dielectric is applied over an area composed in sections of the uncovered sections of the surface of the carrier and the uncovered sections of the surfaces of the gate electrodes, and is patterned as required. The dielectric may be silicon dioxide, aluminum oxide, or an insulating polymer and forms a substrate for the subsequent layers.

A first layer made of an organic semiconductor material is deposited over the substrate (the dielectric) from a solution by printing or spin-on. To that end, a 5% strength solution of regio-regular poly(3-octyl)thiophene in chloroform is spun on at 2000 revolutions per minute and subsequently dried at 60° Celsius.

Afterward, from a second solution, in sections, a thin layer of gold nanoparticles is printed onto the layer made of the organic semiconductor material. The solvent is subsequently driven out at a temperature of 100° Celsius. Finally, a layer made of the contact material is applied to a surface of the layer made of the organic semiconductor material that is opposite to the dielectric. Source and drain contacts are subsequently defined in such a layer.

Preparation of Colloidal Solutions

a) Preparation of a Gold Colloid

A solution with a gold colloid is prepared according to a specification of [G. Jander and E. Blasius, Lehrbuch der analytischen und anorganischen Chemie [Textbook of analytical and inorganic chemistry], 11th edition (1979), page 357]. Accordingly, a 1% strength solution of ammonium tetrachloroaurate (111) is acidified with 0.1% strength hydrochloric acid up to pH 4. Afterward, reduction is effected using a solution of tin (I) chloride in water. A resulting solution of the gold colloid can be applied to a metallic contact material by an inkjet printer. The deposited layer is, then, washed in a nitrogen stream at 18° Celsius for 2 minutes. Finally, excess material is rinsed away with a little water and the substrate is dried in a nitrogen stream at 80° Celsius for 2 minutes.

b) Preparation of a Palladium Colloid

Palladium nanoparticles are produced according to a specification by Hidber [P. C. Hidber et al., Langmuir (1996), page 12 5209]. The nanoparticles are deposited by microcontact printing on the contact material aluminum.

We claim:

1. A method for fabricating a semiconductor device having at least one first body and at least one second body, which comprises:
providing one of the first and second bodies from an organic semiconductor material and providing another one of the first and second bodies from a contact material, the first and second bodies together forming a common contact area therebetween;
providing the first body with a surface;
applying isolated nanoparticles of a particle material on at least sections of the surface of the first body, the contact material and the particle material having different work functions; and
applying the second body at least on sections of the surface of the first body covered by the nanoparticles, the sections of the surface covered by the second body fashioning contact areas.

2. The method according to claim 1, wherein:
the first body is applied as a first layer on a substrate;
the nanoparticles are applied on sections of the surface of the first layer opposite the substrate; and
the second body is applied as a second layer on the contact areas.

3. The method according to claim 1, which further comprises applying the nanoparticles by:
modifying the sections on the surface of the first body; and
applying the nanoparticles at least in the modified sections.

4. The method according to claim 3, wherein the nanoparticles have a surface charge effecting modification of the sections by providing ionic groups on the sections, and which further comprises selectively depositing the nanoparticles in the modified sections during application to the modified sections.

5. The method according to claim 3, wherein:
the nanoparticles have a surface; and
both the modified sections and the surface of the nanoparticles have terminal groups that can react with one another to form a covalent bond and, as a result, fix the nanoparticles in the sections.

6. The method according to claim 3, wherein:
the nanoparticles have surfaces;
the sections are functionalized with a group of a first type;
the surfaces of the nanoparticles are functionalized with a group of a second type; and
the groups of the first and second types are able to react with one another to form an ionic bond and, as a result, fix the nanoparticles in the sections.

7. The method according to claim 1, wherein:
the nanoparticles have a surface;
at least one of the particle material and the material of the first body is one of a metal and a metal compound; and
which further comprises functionalizing one of the surface of the nanoparticles and the surface of the first body with a substance that can form a coordinative bond with one of a metal and a metal compound and, as a result, fix the nanoparticles on the surface of the first body.

8. The method according to claim 1, which further comprises applying the nanoparticles section-by-section with the aid of one of the group consisting of a mask, a stencil, and a printer.

9. The method according to claim 1, which further comprises:
effecting application of the nanoparticles in solution;
producing the nanoparticles in solution with a solvent;
applying the solution to at least sections of the surface of the first body; and
driving out the solvent.

10. The method according to claim 9, which further comprises applying the nanoparticles in a colloidal precursor and coagulating on the sections of the surface of the first body.

11. The method according to claim 9, wherein the solution is applied by one of the group consisting of spin-on, printing, pouring, spraying, and by dipping into the solution.

12. The method according to claim 11, which further comprises applying the nanoparticles in a colloidal precursor and coagulating on the sections of the surface of the first body.

13. The method according to claim 1, which further comprises producing the nanoparticles from a colloidal precursor and coagulating in solution.

14. The method according to claim 1, which further comprises applying the nanoparticles by:
applying a chemical precursor of the particle material; and
converting the precursor into the particle material.

15. The method according to claim 1, which further comprises:
forming a field-effect transistor with a source electrode, a drain electrode, and a path of a semiconductor material disposed between the source electrode and the drain electrode with the first and second bodies; and
locating the contact areas respectively between:
the drain and source electrodes; and
the organic semiconductor material.

16. The method according to claim 9, wherein the particle material is gold and the solution is applied by a printer.

17. The method according to claim 13, wherein the particle material is gold and the solution is applied by a printer.

18. A method for fabricating a field-effect transistor having at least one first body and at least one second body, which comprises:
providing one of the first and second bodies from an organic semiconductor material and providing another one of the first and second bodies from a contact material, the first and second bodies together forming a common contact area therebetween;
providing the first body with a surface;
applying isolated nanoparticles of a particle material on at least sections of the surface of the first body, the contact material and the particle material having different work functions;
applying the second body at least on sections of the surface of the first body covered by the nanoparticles, the sections of the surface covered by the second body fashioning contact areas;
forming the field-effect transistor with a source electrode, a drain electrode, and a path of a semiconductor material disposed between the source electrode and the drain electrode with the first and second bodies; and
locating the contact areas respectively between:
the drain and source electrodes; and
the organic semiconductor material.

19. A semiconductor device configuration, comprising:
at least one first body;
at least one second body, one of said first and second bodies being composed of an organic semiconductor material and another of said first and second bodies being composed of a conductive contact material;
at least one contact area disposed between said at least one first body and said at least one second body; and
nanoparticles incorporated at said contact area, said nanoparticles of a particle material having a different work function than said contact material.

20. The configuration according to claim 19, wherein:
said first body:
has a substrate; and
is disposed at least in sections as a first layer on said substrate;
said first layer has a surface opposite said substrate; and
said second body is disposed at least in sections as a second layer on said surface of said first layer opposite said substrate.

21. The configuration according to claim 19, wherein said particle material is one of the group consisting of a metal and a metal compound.

22. The configuration according to claim 19, wherein said nanoparticles have a mean diameter of between approximately 0.1 nm and approximately 5000 nm.

23. The configuration according to claim 19, wherein:
said nanoparticles have a surface;
said first body has a surface;
an auxiliary layer is disposed between said surface of said nanoparticles and said surface of said first body; and
said auxiliary layer fixes said nanoparticles in sections of said surface during a fabrication process for the semiconductor device.

24. The configuration according to claim 19, wherein:
said nanoparticles have a surface;
said first body has a surface;
an auxiliary layer is disposed between said surface of said nanoparticles and said surface of said first body; and
said auxiliary layer fixes said nanoparticles in sections of at least one of said surface of said nanoparticles and said surface of said first body during fabrication.

25. The configuration according to claim 19,
said particle material and said contact material each have a work function; and
said work function of said particle material and said work function of said contact material differ from one another by at least approximately 0.3 eV.
